(19) United States
(12) Patent Application Publication
(10) Pub. No.: US 2022/0165991 A1
(43) Pub. Date: May 26, 2022

(54) OLED DISPLAY PANEL AND METHOD OF MANUFACTURING THE SAME, AND OLED DISPLAY APPARATUS

(71) Applicants: CHENGDU BOE OPTOELECTRONICS TECHNOLOGY CO., LTD., Sichuan (CN); BOE TECHNOLOGY GROUP CO., LTD, Beijing (CN)

(72) Inventors: Lin ZHANG, Beijing (CN); Xin MOU, Beijing (CN); Xing HUANG, Beijing (CN)

(21) Appl. No.: 17/437,084

(22) PCT Filed: Nov. 26, 2020
(86) PCT No.: PCT/CN2020/131626

§ 371 Date: Sep. 8, 2021

(30) Foreign Application Priority Data
Dec. 13, 2019 (CN) 201911285804.X

(51) Int. Cl. H01L 51/52; H01L 27/32; H01L 51/56

(52) U.S. Cl. CPC H01L 51/5265; H01L 27/322; H01L 51/56; B60R 1/22; H01L 27/3244; H01L 2227/323; H01L 2251/5315; H01L 27/3211

(57) ABSTRACT

An OLED display panel has a display region including sub-pixel regions. The sub-pixel regions include red sub-pixel regions. The OLED display panel includes: a base, light-emitting devices disposed on the base and located in the red sub-pixel regions, and color resist layers disposed in the red sub-pixel regions and located at light-exit sides of the light-emitting devices. A light-emitting device has a microcavity structure, and a length of the microcavity of the light-emitting device is in a range from 100 nm to 500 nm. The light-emitting device is configured to emit red light. The color resist layer is configured such that a transmittance of light with a wavelength of 585 nm or above is greater than a transmittance of light with a wavelength of below 585 nm.

### CROSS-REFERENCE TO RELATED APPLICATIONS

This application is a national phase entry under 35 USC 371 of International Patent Application No. PCT/CN2020/131626, filed on Nov. 26, 2020, which claims priority to Chinese Patent Application No. 201911285804.X, filed on Dec. 13, 2019, which are incorporated herein by reference in their entirety.

### TECHNICAL FIELD

The present disclosure relates to the field of display technologies, and in particular, to an OLED display panel and a method of manufacturing the same, and an OLED display apparatus.

### BACKGROUND

Organic light-emitting diode (OLED) display technology is a technology that uses organic light-emitting materials to emit light and achieve display under the drive of current.

### SUMMARY

In one aspect, an OLED display panel is provided. The display panel has a display region including a plurality of sub-pixel regions. The plurality of sub-pixel regions include red sub-pixel regions. The OLED display panel includes a base, light-emitting devices and color resist layers. The light-emitting devices are disposed on the base and located in the red sub-pixel regions. A light-emitting device has a microcavity structure, and a length of the microcavity of the light-emitting device is in a range from 100 nm to 500 nm. The light-emitting device is configured to emit red light. The color resist layers are disposed in the red sub-pixel regions and located at a light-exit sides of the light-emitting devices. A color resist layer is configured such that a transmittance of light with a wavelength of 585 nm or above is greater than a transmittance of light with a wavelength of below 585 nm.

In some embodiments, the color resist layer is configured such that a transmittance of light with a wavelength of 595 nm or above is greater than a transmittance of light with a wavelength of below 595 nm.

In some embodiments, the color resist layer is configured such that a transmittance of light with a wavelength of 605 nm or above is greater than a transmittance of light with a wavelength of below 605 nm.

In some embodiments, the length of the microcavity of the light-emitting device is greater than 200 nm and less than 500 nm.

In some embodiments, the length of the microcavity of the light-emitting device is greater than 200 nm and less than or equal to 350 nm.

In some embodiments, the length of the microcavity of the light-emitting device is greater than 200 nm and less than or equal to 330 nm.

In some embodiments, the length of the microcavity of the light-emitting device is greater than 200 nm and less than or equal to 300 nm.

In some embodiments, the color resist layer is made of an organic polymer.

In some embodiments, the OLED display panel further includes an encapsulation layer. The encapsulation layer is disposed on a side of the light-emitting device away from the base.

In some embodiments, the OLED display panel further includes pixel driving circuits. The pixel driving circuits are disposed between the light-emitting devices and the base. A pixel driving circuit is configured to drive the light-emitting device to emit light.

In some embodiments, the plurality of sub-pixel regions further include green sub-pixel regions adjacent to the red sub-pixel regions. The color resist layer is also located in a region between the red sub-pixel region and a green sub-pixel region.

In some embodiments, the plurality of sub-pixel regions further include blue sub-pixel regions adjacent to the red sub-pixel regions, The color resist layer is also located in a region between the red sub-pixel region and a blue sub-pixel region.

In another aspect, an OLED display apparatus is provided. The OLED display apparatus includes the OLED display panel as described above.

In yet another aspect, a method of manufacturing an OLED display panel is to provided. The OLED display panel has a display region including a plurality of sub-pixel regions. The plurality of sub-pixel regions include red sub-pixel regions. The method includes: forming light-emitting devices on a base and in the red sub-pixel regions; and forming color resist layers in the red sub-pixel regions and at light-exit sides of the light-emitting devices, A light-emitting device has a microcavity structure, and a length of the microcavity of the light-emitting device is in a range from 100 nm to 500 nm. The light-emitting device is configured to emit red light. A color resist layer is configured such that a transmittance of light with a wavelength of 585 nm or above is greater than a transmittance of light with a wavelength of below 585 nm.

In some embodiments, the light-emitting devices are top-emission light-emitting devices. Forming the light-emitting devices and the color resist layers includes: forming the color resist layers on an encapsulation layer; and encapsulating the light-emitting devices by using the encapsulation layer on which the color resist layers have been formed, so that the color resist layers are located between the light-emitting devices and the encapsulation layer.

In some embodiments, the light-emitting devices are top-emission light-emitting devices. Forming the light-emitting devices and the color resist layers includes forming the light-emitting devices, an encapsulation layer and the color resist layers sequentially on the base.

In some embodiments, the light-emitting devices are top-emission light-emitting devices, and the color resist layers are arranged on a side of the encapsulation layer away from the light-emitting devices.

In some embodiments, the light-emitting devices are top-emission light-emitting devices, and the color resist layers are arranged between the encapsulation layer and the light-emitting devices.

In some embodiments, the light-emitting devices are bottom-emission light-emitting devices, and the color resist layers, the light-emitting devices and the encapsulation layer are sequentially arranged on the base.

In some embodiments, the light-emitting devices are bottom-emission light-emitting devices. Forming the light-emitting devices and the color resist layers includes forming the color resist layers, the light-emitting devices and an encapsulation layer sequentially on the base.

### BRIEF DESCRIPTION OF THE DRAWINGS

In order to describe technical solutions in embodiments of the present disclosure or in the prior art more clearly, accompanying drawings to be used in the description of some embodiments of the present disclosure or the prior art will be briefly introduced below. Obviously, the accompanying drawings to be described below are merely accompanying drawings of some embodiments of the present disclosure, and a person of ordinary skill in the art may obtain other drawings according to these drawings. In addition, the accompanying drawings to be described below may be regarded as schematic diagrams, but are not limitations on an actual size of a product and an actual process of a method involved in the embodiments of the present disclosure.

FIG. 1 is a schematic structural diagram of an OLED display apparatus, in accordance with some embodiments of the present disclosure;

FIG. 2 is a schematic top view of an OLED display panel, in accordance with some embodiments of the present disclosure;

FIG. 3A is a sectional view of the OLED display panel in FIG. 2 taken along the line I-I′;

FIG. 3B is another sectional view of the OLED display panel in FIG. 2 taken along the line I-I′;

FIG. 3C is yet another sectional view of the OLED display panel in FIG. 2 taken along the line I-I′;

FIG. 3D is yet another sectional view of he OLED display panel in FIG. 2 taken along the line I-I′;

FIG. 3E is yet another sectional view of the OLED display panel n FIG. 2 taken along the line I-I′;

FIG. 3F is yet another sectional view of the OLED display panel in FIG. 2 taken along the line I-I′;

FIG. 4 is a spectrum diagram of red light emitted by an OLED display panel, in accordance with some embodiments of the present disclosure;

FIG. 5 is a spectrum diagram of red light emitted by another OLED display panel, in accordance with some embodiments of the present disclosure;

FIG. 6 is a spectrum diagram of red light emitted by yet another OLED display panel, in accordance with some embodiments of the present disclosure;

FIG. 7 is a spectrum diagram of red light emitted by yet another OLED display panel, in accordance with some embodiments of the present disclosure;

FIG. 8 is a spectrum diagram of red light emitted by yet another OLED display panel, in accordance with some embodiments of the present disclosure;

FIGS. 9 to 11 are diagrams illustrating a process of manufacturing an OLED display panel, in accordance with some embodiments of the present disclosure;

FIG. 12 is a diagram illustrating a process of manufacturing another OLED display panel, in accordance with some embodiments of the present disclosure; and

FIG. 13 is a diagram illustrating a process of manufacturing yet another OLED display panel, in accordance with some embodiments of the present disclosure.

### DETAILED DESCRIPTION

Technical solutions in some embodiments of the present disclosure will be described below clearly and completely with reference to the accompanying drawings in the embodiments of the present disclosure. Obviously, the described embodiments are merely some but not all embodiments of the present disclosure. All other embodiments obtained on the basis of the embodiments of the present disclosure by a person of ordinary skill in the art shall be included in the protection scope of the present disclosure.

As used herein, the singular form “a/an” also includes the plural form, unless the context clearly dictates otherwise. Unless the context requires otherwise, throughout the description and the claims, the term “comprise” and other forms thereof such as the third-person singular form “comprises” and the present participle form “comprising” are construed as an open and inclusive meaning, i.e., “including, but not limited to.” In the description of the specification, terms such as “some embodiments”, “example” or “some examples” are intended to indicate that specific features, structures, materials or characteristics related to the embodiment(s) or example(s) are included in at least one embodiment or example of the present disclosure. Schematic representations of the above terms do not necessarily refer to the same embodiment(s) or example(s). In addition, the specific features, structures, materials, or characteristics may be included in any or more embodiments or examples in any suitable manner.

Hereinafter, the terms such as “first” and “second” are only used for descriptive purposes, and are not to be construed as indicating or implying relative importance or implicitly indicating the number of indicated technical features. Thus, a feature defined by “first” or “second” may explicitly or implicitly include one or more of the features.

Use of the phrase “configured to” means an open and inclusive expression, which does not exclude devices configured to perform additional tasks or steps.

Terms such as “about” as used herein include a stated value and an average value within an acceptable range of deviation of a particular value. The acceptable range of deviation is determined by a person of ordinary skill in the art in view of the measurement in question and the error associated with the measurement of a particular quantity (i.e., the limitations of the measurement system).

Exemplary embodiments are described herein with reference to cross-sectional views and/or plan views as idealized exemplary drawings. In the accompanying drawings, thicknesses of layers and sizes of regions are enlarged for clarity. Therefore, the exemplary embodiments should not be construed as being limited to the shapes of the areas shown herein, but including shape deviations due to, for example, manufacturing. The areas shown in the accompanying drawings are schematic in nature, and their shapes are not intended to show actual shapes of the areas in a device, and are not intended to limit the scope of the exemplary embodiments.

An organic light-emitting diode (OLED) display apparatus may be used as a product or a component having any display function, such as a mobile phone, a tablet computer, a personal digital assistant (FDA), a vehicle-mounted display, a TV, a digital photo frame or a navigator, which is not limited in embodiments of the present disclosure.

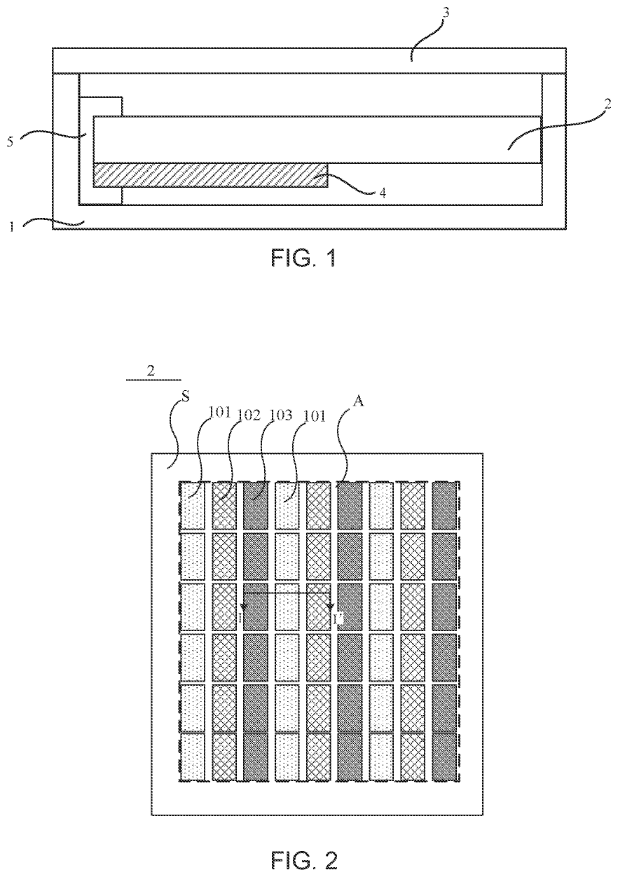

In some embodiments, as shown in FIG. 1, the OLED display apparatus includes a frame 1, an OLED display panel 2, a cover plate 3, a circuit board 4 and a flexible printed circuit (FPC) 5. Of course, the OLED display apparatus may include more or fewer components, and relative positions of these components may be changed.

For example, a section of the frame 1 is U-shaped. The OLED display panel 2, the circuit board 4 and the FPC 5 are disposed in a cavity enclosed by the frame 1 and the cover plate 3. The cover plate 3 is disposed at a light-exit side of the OLED display panel 2. An end of the FPC 5 is bonded to an edge of the OLED display panel 2, and another end of the FPC 5 is bonded to the circuit board 4. The circuit board 4 is disposed on a side of the OLED display panel 2 facing away from the cover plate 3.

In some examples, the FPC 5 includes a FPC body and at least one driver chip disposed on the FPC body. The driver chip may be a driver integrate circuit (10). For example, at least one driver IC includes at least one data driver IC.

In some examples, the circuit board 4 is configured to provide the OLED display panel 2 with signals required for display. For example, the circuit board 4 is a printed circuit board assembly (PCBA), and the PCBA includes a printed circuit board (PCB) and a timing controller (TCON), a power management IC (PMIC), and other ICs or circuits that are disposed on the PCB.

Some embodiments of the present disclosure provide the OLED display panel 2. As shown in FIG. 2, the OLED display panel 2 has a display region A, and the display region A includes a plurality of sub-pixel regions. The plurality of sub-pixel regions include red sub-pixel regions 101. In some embodiments, the OLED display panel 2 further has a peripheral region S. In some examples, the peripheral region S is disposed around the display region A. In some other examples, the peripheral region S is only located at one side of the display region A. In yet some other examples, the peripheral region S is located at two opposite sides of the display region A. The peripheral region S is used for wiring, and of course, the peripheral region S may also be provided with driving circuit(s), such as a gate driving circuit, etc. FIG. 2 illustrates an example in which the peripheral region S is disposed around the display region A, and the plurality of sub-pixel regions are arranged in a matrix.

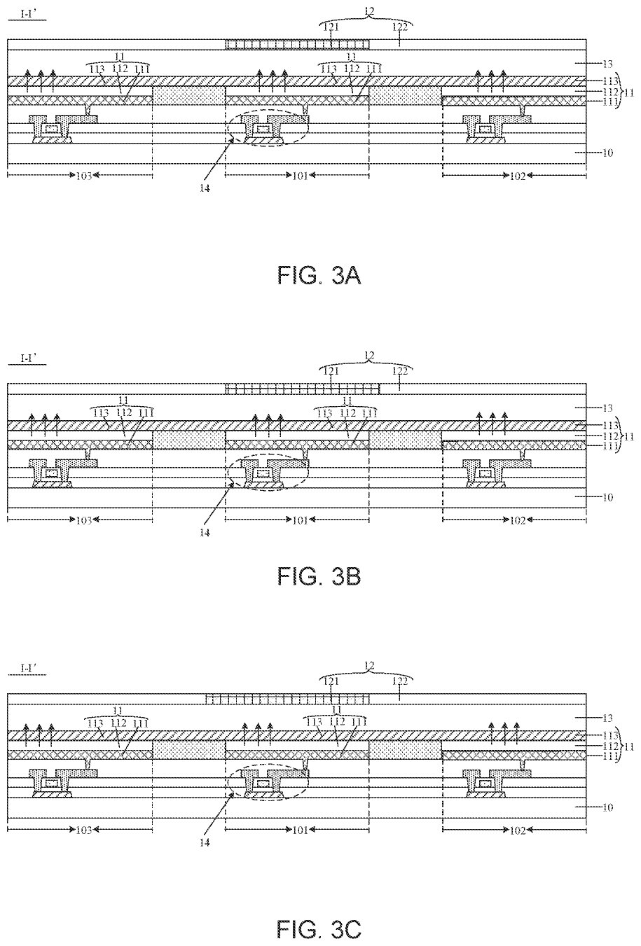

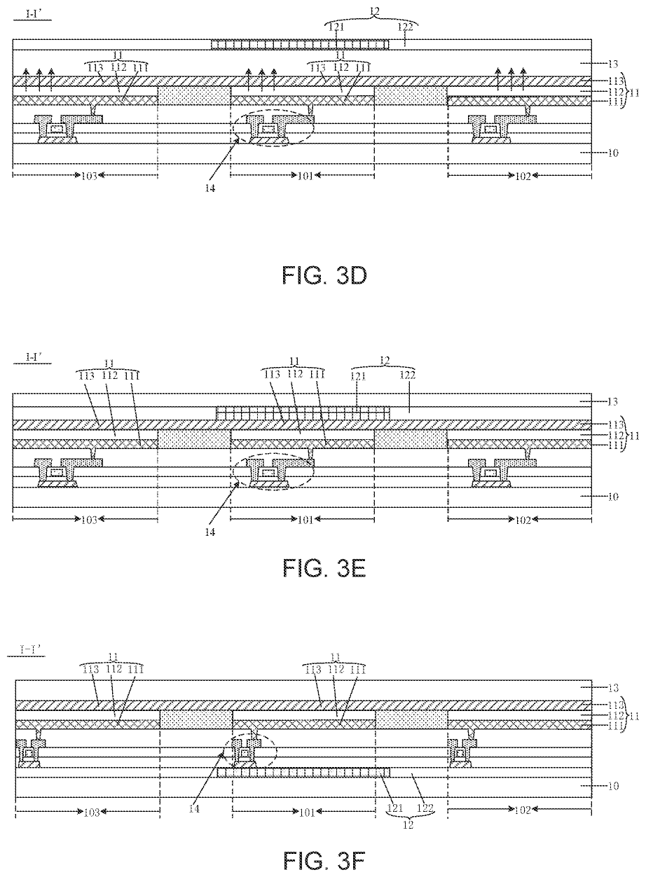

As shown in FIGS. 3A to 3F, the OLED display panel 2 includes a base 10, light-emitting devices 11 disposed on the base 10 and located in the red sub-pixel regions 101, and color resist layers 121 disposed in the red sub-pixel regions 101 and located at light-exit sides of the light-emitting devices 11. The light-emitting device 11 has a microcavity structure, and a length of the microcavity of the light-emitting device 11 is in a range from 100 nm to 500 nm, The light-emitting device 11 located in the red sub-pixel region 101 is configured to emit red light. The color resist layer 121 is configured such that a transmittance of light with a wavelength of 585 nm or above is greater than a transmittance of light with a wavelength of below 585 nm.

Here, the microcavity structure means that a structure of the light-emitting device 11 satisfies a microcavity effect. The microcavity effect is as follows: in a case where a light-emitting region of the light-emitting device 11 is located in a resonant cavity formed by a total reflection electrode and a semi-reflection electrode, and a cavity length of the resonant cavity is in the same order of magnitude as a wavelength of light, light with a specific wavelength is selected and strengthened to narrow a spectrum. Based on this, the length of the microcavity is the cavity length of the resonant cavity.

In some examples, as shown in FIGS. 3A to 3F, the light-emitting device 11 includes a first electrode 111, a light-emitting functional layer 112 and a second electrode 113 that are sequentially arranged in a thickness direction of the base 10. The light-emitting functional layer 112 includes a light-emitting layer, and the light-emitting layer is configured to emit light. One of the first electrode 111 and the second electrode 113 is a reflective electrode, and the other is a transflective electrode, For example, the first electrode 111 is an anode, and the second electrode 113 is a cathode. For another example, the first electrode 111 is a cathode, and the second electrode 113 is an anode.

The light-emitting device 11 may be a top-emission light-emitting device or a bottom-emission light-emitting device. By taking an example in which the first electrode 111 is the anode and the second electrode 113 is the cathode, in a case where the light-emitting device 11 is the top-emission light-emitting device, the second electrode 113 is the transflective electrode, and the first electrode 111 is the reflective electrode. The first electrode 111 is, for example, a stacked structure including a transparent conductive sub-electrode and at least one opaque metal sub-electrode, and the second electrode 113 is a metal electrode with a relatively small thickness; in a case where the light-emitting device 11 is the bottom-emission light-emitting device, the first electrode 111 is th transflective electrode, and the second electrode 113 is the reflective electrode. The first electrode 111 is, for example, a stacked structure including a transparent conductive sub-electrode and at least one metal sub-electrode, a thickness of the at least one metal sub-electrode is relatively small, and the second electrode 113 is an opaque metal electrode.

The length of the microcavity of the light-emitting device 11 is a distance from a surface of the first electrode 111 proximate to the second electrode 113 to a surface of the second electrode 113 proximate to the first electrode 111.

As described above, the OLED display panel 2 may be applied to a vehicle-mounted display in a vehicle. The vehicle-mounted display may be used to display road condition information, driving information and the like, so as to facilitate safe driving of a driver. European vehicle regulations have strict requirements on a dominant wavelength of red light emitted by a vehicle-mounted display. The European vehicle regulations require that color of the red light should be dark red. That is, the dominant wavelength of the red light should be in a range from 618 nm to 630 nm, and a center value of the dominant wavelength of the red light is 623 nm.

However, the color of the red light of the current display is not deep enough, and the dominant wavelength thereof may only reach 613 nm at a maximum, which is unable to meet the requirements of the European vehicle regulations.

In the OLED display panel 2 provided in some embodiments of the present disclosure, the color resist layer 121 is provided in the red sub-pixel region 101 and on the light-exit side of the light-emitting device 11 to make the transmittance of the light with the wavelength of 585 nm or above emitted by the light-emitting device 11 greater than the transmittance of the light with the wavelength of below 585 nm emitted by the light-emitting device 11. That is, the color resist layer 121 may filter most of the light with the wavelength of below 585 nm, redshift a spectrum of light passing through the color resist layer 121, and narrow a high transmission band of the red light passing through the color resist layer 121. As a result, a dominant wavelength of the light passing through the color resist layer 121 is increased. On this basis, the light emitted by the light-emitting functional layer 112 is reflected multiple tunes in the resonant cavity and the reflected light interferes with each other, and finally a spectrum of light emitted from the light-emitting device 11 forms an OLED display spectrum. By setting the length of the microcavity of the light-emitting device 11 to be in a range from 100 nm to 500 nm, a color coordinates of the OLED display spectrum shifts toward a long wavelength relative to an intrinsic spectrum, so as to further increase the dominant wavelength of the light passing through the color resist layer 121, and thus the red light emitted by the OLED display panel 2 is dark red, which meets the European vehicle regulations.

In some embodiments, the base 10 may be a flexible base or a rigid base. For example, the flexible base is made of polyimide (PI) or polyethylene terephthalate (PET). For example, the rigid base is made of glass.

In some embodiments, the color resist layers 121 are only disposed in the red sub-pixel regions 101. In some examples, as shown in FIG. 3A, an area of a surface of the color resist layer 121 proximate to the light-emitting device 11 is equal to an area of the red sub-pixel region 101. In some other examples, an area of the surface of the color resist layer 121 proximate to the light-emitting device 11 is smaller than the area of the red sub-pixel region 101.

In some other embodiments, the color resist layer 121 extends from the red sub-pixel region 101 to a region between the red sub-pixel region 101 and a sub-pixel region adjacent thereto.

In some examples, as shown in FIG. 2, the plurality of sub-pixel regions include the red sub-pixel regions 101 and green sub-pixel regions 102 adjacent thereto. As shown in FIG. 3B, the color resist layer 121 is located in the red sub-pixel region 101 and a region between the red sub-pixel region 101 and the green sub-pixel region 102 adjacent thereto.

In some other examples, as shown in FIG. 2, the plurality of sub-pixel regions include the red sub-pixel regions 101 and blue sub-pixel regions 103 adjacent thereto. As shown in FIG. 3C, the color resist layer 121 is located in the red sub-pixel region 101 and a region between the red sub-pixel region 101 and the blue sub-pixel regions 103 adjacent thereto.

In yet some other examples, as shown in FIG. 2, the plurality of sub-pixel regions include the red sub-pixel regions 101, the green sub-pixel regions 102 adjacent to the red sub-pixel regions 101, and the blue sub-pixel regions 103 adjacent to the red sub-pixel regions 101, As shown in FIGS. 3D to 3F, the color resist layer 121 is located in the red sub-pixel region 101, the region between the red sub-pixel region 101 and the green sub-pixel region 102 adjacent thereto, and the region between the red sub-pixel region 101 and the blue sub-pixel region 103 adjacent thereto.

Each of the green sub-pixel region 102 and the blue sub-pixel region 103 is provided with a light-emitting device 11, The light-emitting device 11 located in the red sub-pixel region 101 is configured to emit red light, the light-emitting device 11 located in the green sub-pixel region 102 is configured to emit green light, and the light-emitting device 11 located in the blue sub-pixel region 103 is configured to emit blue light.

In the case where the color resist layer 121 is located in the red sub-pixel region 101, the region between the red sub-pixel regions 101 and the adjacent green sub-pixel region 102, and the region between the red sub-pixel region 101 and the adjacent blue sub-pixel region 103, in the light emitted by the light-emitting device 11 located in the red sub-pixel region 101, not only light in a vertical direction tcan be incident onto the color resist layer 121, but also light at other angles can be incident onto the color resist layer 121. Therefore, it is ensured that the color resist layer 121 is able to filter light at all angles.

Hereinafter, the OLED display panel 2 will be described by taking an example where the display region A includes the red sub-pixel regions 101, the green sub-pixel regions 102 and the blue sub-pixel regions 103.

In some embodiments, the OLED display panel 2 further includes a pixel driving circuit located in each sub-pixel region and disposed between the base 10 and the light-emitting device 11. The pixel driving circuit is configured to drive the light-emitting device 11 to emit light. The pixel driving circuit includes a plurality of transistors and a capacitor. The base 10 and the pixel driving circuit disposed thereon constitute an array substrate of the OLED display panel 2.

The plurality of transistors include at least two switching transistors and a driving transistor, and one of the plurality of transistors is electrically connected to the light-emitting device 11 (e.g., the first electrode 111 of the light-emitting device 11). As shown in FIGS. 3A to 3F, an example in which the driving transistor 14 is connected to the light-emitting device 11 is illustrated.

In some examples, the switching transistors and the driving transistor 14 are thin film transistors. The thin film transistors may be top-gate thin film transistors, bottom-gate thin film transistors or double-gate thin film transistors.

It will be noted that, in order to make light emitted by the light-emitting device 11 located in the green sub-pixel region 102 and light emitted by the light-emitting device 11 located in the blue sub-pixel region 103 exit normally, and the color resist layer 121 is only used to filter the light emitted by the light-emitting device 11 located in the red sub-pixel region 101, the color resist layer 121 is not located in the green sub-pixel region 102 and the blue sub-pixel region 103.

A material of the color resist layer 121 is not limited in the embodiments of the present disclosure, as long as the color resist layer 121 may make the transmittance of the light with the wavelength of 585 nm or above greater than the transmittance of the light with the wavelength of below 585 nm.

In some examples, the color resist layer 121 is made of an organic polymer. For example, the organic polymer is polymerized by organic pigment, dispersion resin, multifunctional acrylic monomer, high boiling point solvent and other additives. The spectrum of the light passing through the color resist layer 121 is mainly determined by the organic pigment in the organic polymer, The smaller a molecular structure of the organic pigment is, the higher a transmittance of the color resist layer 121 is. In addition, the spectrum of the light passing through the color resist layer 121 is also related to a ratio of various materials and a preparation process during preparing the organic polymer.

For example, the organic pigment is a diketopyrrolopyrrole organic pigment. For example, the high boiling point solvent is polymethacrylates (PMA).

In some embodiments, as shown in FIGS. 3A to 3D and 3F, the OLED display panel 2 further includes light-transmitting layers 122, and orthogonal projections of the light-transmitting layers 122 on the base 10 do not overlap with orthogonal projections of the color resist layers 121 on the base 10. In some examples, the light-transmitting layer 122s are located in the green sub-pixel regions 102 and the blue sub-pixel regions 103.

For example, as shown in FIGS. 3A to 3D and 3F, the light-transmitting layers 122 and the color resist layers 121 constitute a filter layer 12. That is, the light-transmitting layers 122 and the color resist layers 121 are located on a surface of the same layer. For example, surfaces of the light-transmitting layers 122 away from the base 10 are flush with surfaces of the color resist layers 121 away from the base 10.

A material of the light-transmitting layers 122 is not limited in the embodiments of the present disclosure, as long as it does not affect normal exiting of the light emitted by the light-emitting device 11 located in the green sub-pixel region 102 and the light-emitting device 11 located in the blue sub-pixel region 103.

In some examples, the material of the light-transmitting layer 122 includes a material having high transmittance such as Pl.

In some embodiments, as shown in FIGS. 3A to 3F, the OLED display panel 2 further includes an encapsulation layer 13 disposed on a side of the light-emitting devices 11 away from the base 10. The encapsulation layer 13 may be a flexible encapsulation layer or a rigid encapsulation substrate. The rigid encapsulation substrate has stronger resistance to deformation relative to the flexible encapsulation layer, that is, the flexible encapsulation layer is more easily deformed due to an action of external force, while the rigid encapsulation substrate is not easily deformed due to the action of external force. By providing the encapsulation layer 13, it is possible to prevent moisture and oxygen from entering the light-emitting device 11 to affect a service life of the light-emitting device 11.

In some examples, as shown in FIGS. 3A to 3D, the light-emitting devices 11 are the top-emission light-emitting devices, and the filter layers 12 are disposed on a side of the encapsulation layer 13 away from the light-emitting device 11. Based on this, the OLED display panel 2 may be formed by sequentially stacking the light-emitting devices 11, the encapsulation layer 13 and the filter layers 12 on the base 10. In this case, the encapsulation layer 13 may be a flexible encapsulation layer.

In some other examples, as shown in FIG. 3E, the light-emitting devices 11 are the top-emission light-emitting devices, the encapsulation layer 13 is a rigid encapsulation substrate, and the filter layers 12 are disposed on a side of the encapsulation layer 13 proximate to the light-emitting devices 11. In this case, the OLED display panel 2 may be formed as follows: forming the light-emitting devices 11 on the base 10, forming the filter layers 12 on the encapsulation layer 13, and then encapsulating the light-emitting devices 11 by using the encapsulation layer 13 on which the filter layers 12 have been formed.

In some other examples, as shown in FIG. 3F, the light-emitting devices 11 are the bottom-emission light-emitting devices, and the filter layers 12 are disposed on a side of the light-emitting devices 11 away from the encapsulation layer 13. For example, as shown in FIG. 3F, the filter layers 12 are disposed on a side of the light-emitting devices 11 proximate to the base 10. In this case, the OLED display panel 2 may be formed by sequentially stacking the filter layers 12, the light-emitting devices 11 and the encapsulation layer 13 on the base 10. It will be noted that, FIG. 3F illustrates that the filter layer 12 is in contact with the driving transistor 14, but the embodiments of the present disclosure are not limited thereto, and other layers may be provided between the driving transistor 14 and the filter layer 12. For another example, the filter layers 12 are disposed on a side of the base 10 away from the light-emitting devices 11

In some embodiments, the color resist layer 121 is configured such that a transmittance of light with a wavelength of 595 nm or above is greater than a transmittance of light with a wavelength of below 595 nm.

In some other embodiments, the color resist layer 121 is configured such that a transmittance of light with a wavelength of 605 nm or above is greater than a transmittance of light with a wavelength of below 605 nm.

In some embodiments, the length of the microcavity of the light-emitting device 11 is greater than 200 nm and less than 500 nm.

In some examples, the length of the microcavity of the light-emitting device 11 is greater than 200 nm and less than or equal to 350 nm For example, the length of the microcavity of the light-emitting device 11 is 275 nm.

In some other examples, the length of the microcavity of the light-emitting device 11 is greater than 200 nm and less than or equal to 330 nm. For example, the length of the microcavity of the light-emitting device 11 is 265 nm,

In yet some other examples, the length of the microcavity of the light-emitting device 11 is greater than 200 nm and less than or equal to 300 nm. For example, the length of the microcavity of the light-emitting device 11 is 250 nm.

Hereinafter, spectrum diagrams of red light emitted by OLED display panels 2 provided in the embodiments of the present disclosure are obtained through simulation, and the dominant wavelength is determined according to color coordinates of the emitted red light.

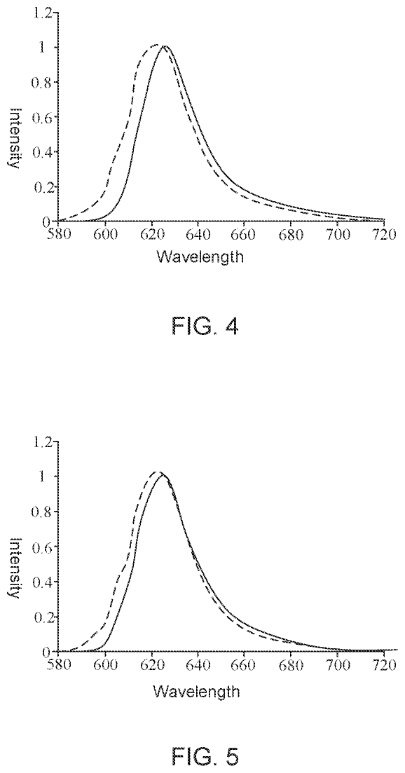

FIG. 4 is a diagram illustrates a spectrum (as shown by the dotted line in FIG. 4) of red light emitted by the OLED display panel 2 in a case where the length of the microcavity is in the range from 200 nm to 350 nm, and a spectrum (as shown by the solid line in FIG. 4) of red light emitted by the OLED display panel 2 in a case where the length of the microcavity is in the range from 200 nm to 350 nm and the color resist layer 121 is configured such that the transmittance of the light with the wavelength of 605 nm or above is greater than the transmittance of the light with the wavelength of below 605 nm. It will be seen from FIG. 4 that an emission peak of the red light of the spectrum shown by the solid line is about 627 nm. Compared with the case where only the length of the microcavity is set to be in the range from 200 nm to 350 nm (as shown by the dotted line in FIG. 4), in the case where the length of the microcavity is set to be in the range from 200 nm to 350 nm and the color resist layer 121 is configured to make the transmittance of the light with the wavelength of 605 nm or above greater than the transmittance of the light with the wavelength of below 605 nm (as shown by the solid line in FIG. 4), the dominant wavelength of red light emitted by the OLED display panel 2 is increased by 6 nm to 8 nm, and the dominant wavelength of the red light is in a range from 622 nm to 624 nm, which meets the standards of European vehicle regulations.

FIG. 5 is a diagram illustrates a spectrum (as shown by the dotted line in FIG. 5) of red light emitted by the OLED display panel 2 in a case where the length of the microcavity is in the range from 200 nm to 350 nm, and a spectrum (as shown by the solid line in FIG. 5) of red light emitted by the OLED display panel 2 in a case where the length of the microcavity is in the range from 200 nm to 350 nm and the color resist layer 121 is configured such that the transmittance of the light with the wavelength of 595 nm or above is greater than the transmittance of the light with the wavelength of below 595 nm. It will be seen from FIG. 5 that an emission peak of the red light of the spectrum shown by the solid line is about 626 nm. Compared with the case where only the length of the microcavity is set to be in the range from 200 nm to 350 nm (as shown by the dotted line in FIG. 5), in the case where the length of the microcavity is in the range from 200 nm to 350 nm and the color resist layer 121 is configured such that the transmittance of the light with the wavelength of 595 nm or above is greater than the transmittance of the light with the wavelength of below 595 nm (as shown by the solid line in FIG. 5), the dominant wavelength of red light emitted by the OLED display panel 2 is increased by 3 nm to 4 nm, and the dominant wavelength of the red light is in a range from 619 nm to 620 nm, which meets the standards of European vehicle regulations.

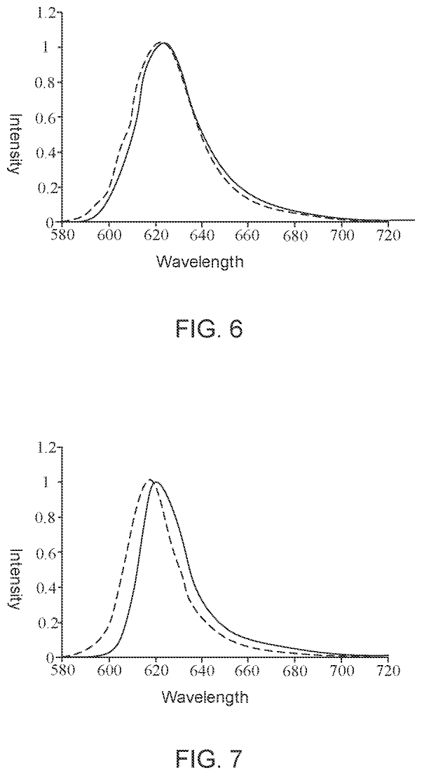

FIG. 6 is a diagram illustrates a spectrum (as shown by the dotted line in FIG. 6) of red light emitted by the OLED display panel 2 in a case where the length of the microcavity is in the range from 200 nm to 350 nm, and a spectrum (as shown by the solid line in FIG. 6) of red light emitted by the OLED display panel 2 in a case where the length of the microcavity is in the range from 200 nm to 350 nm and the color resist layer 121 is configured such that the transmittance of the light with the wavelength of 585 nm or above is greater than the transmittance of the light with the wavelength of below 585 nm. It will be seen from FIG. 6 that an emission peak of the red light of the spectrum shown by the solid line is about 626 nm. Compared with the case where only the length of the microcavity is set to be in the range from 200 nm to 350 nm (as shown by the dotted line in FIG. 6), in the case where the length of the microcavity is in the range from 200 nm to 350 nm and the color resist layer 121 is configured such that the transmittance of the light with the wavelength of 585 nm or above is greater than the transmittance of the light with the wavelength of below 585 nm (as shown by the solid line in FIG. 6), the dominant wavelength of red light emitted by the OLED display panel 2 is increased by 2 nm to 3 nm, and the dominant wavelength of the red light is in a range from 618 nm to 619 nm, which meets the standards of European vehicle regulations.

FIG. 7 is a diagram illustrates a spectrum (as shown by the dotted line in FIG. 7) of red light emitted by the OLED display panel 2 in a case where the length of the microcavity is in the range from 200 nm to 330 nm, and a spectrum (as shown by the solid line in FIG. 7) of red light emitted by the OLED display panel 2 in a case where the length of the microcavity is in the range from 200 nm to 330 nm and the color resist layer 121 is configured such that the transmittance of the light with the wavelength of 605 nm or above is greater than the transmittance of the light with the wavelength of below 605 nm. It will be seen from FIG. 7 that an emission peak of the red light of the spectrum shown by the solid line is about 622 nm. Compared with the case where only the length of the microcavity is set to be in the range from 200 nm to 330 nm (as shown by the dotted line in FIG. 7), in the case where the length of the microcavity is in the range from 200 nm to 330 nm and the color resist layer 121 is configured such that the transmittance of the light with the wavelength of 605 nm or above is greater than the transmittance of the light with the wavelength of below 605 nm (as shown by the solid line in FIG. 7), the dominant wavelength of red light emitted by the OLED display panel 2 is increased by 5 nm to 6 nm, and the dominant wavelength of the red light is in a range from 620 nm to 621 nm, which meets the standards of European vehicle regulations.

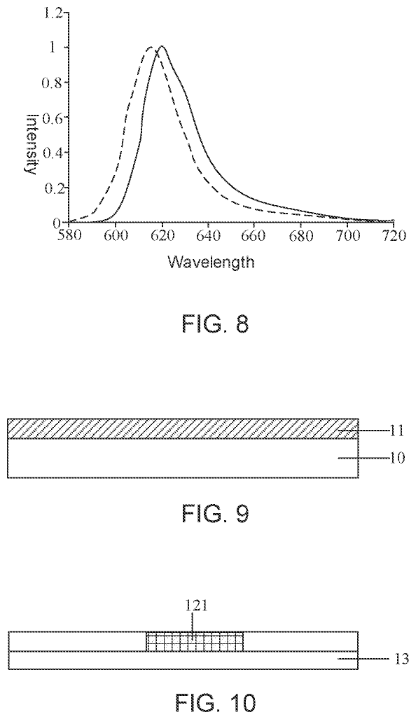

FIG. 8 is a diagram illustrates a spectrum (as shown by the dotted line in FIG. 8) of red light emitted by the OLED display panel 2 in a case where the length of the microcavity is in the range from 200 nm to 300 nm, and a spectrum (as shown by the solid line in FIG. 8) of red light emitted by the OLED display panel 2 in a case where the length of the microcavity is in the range from 200 nm to 300 nm and the color resist layer 121 is configured such that the transmittance of the light with the wavelength of 605 nm or above is greater than the transmittance of the light with the wavelength of below 605 nm. It will be seen from FIG. 8 that an emission peak of the red light of the spectrum shown by the solid line is about 620 nm. Compared with the case where only the length of the microcavity is set to be in the range from 200 nm to 300 nm (as shown by the dotted line in FIG. 8), in the case where the length of the microcavity is in the range from 200 nm to 300 nm and the color resist layer 121 is configured such that the transmittance of the light with the wavelength of 605 nm or above is greater than the transmittance of the light with the wavelength of below 605 nm shown by the solid line in FIG. 8), the dominant wavelength of red light emitted by the OLED display panel 2 is increased by 6 nm to 7 nm, and the dominant wavelength of the red light is in a range from 619 nm to 620 nm, which meets the standards of European vehicle regulations.

In summary, the dominant wavelength of the red light emitted by the OLED display panel 2 provided in the embodiments of the present disclosure meets the standards of European vehicle regulations.

Some embodiments of the present disclosure further provide a method of manufacturing an OLED display panel. As shown in FIG. 2, the OLED display panel 2 has a display region A, and the display region A includes red sub-pixel regions 101.

The method includes: forming light-emitting devices 11 on a base 10 and in the red sub-pixel regions 101, and forming color resist layers 121 in the red sub-pixel regions 101 and at a light-exit side of the light-emitting devices 11. The light-emitting device 11 has a microcavity structure, and a length of the microcavity of the light-emitting device 11 is in a range from 100 nm to 500 nm, The light-emitting devices 11 located in the red sub-pixel regions 101 are configured to emit red light. The color resist layers 121 are configured such that the transmittance of the light with a wavelength of 585 nm or above is greater than the transmittance of the light with a wavelength of below 585 nm,

A sequence of manufacturing the color resist layer 121 and the light-emitting device 11 is not limited in the embodiments of the present disclosure, as long as the color resist layer 121 is located at the light-exit side of the light-emitting device 11.

In some embodiments, the light-emitting device 11 is a top-emission light-emitting device.

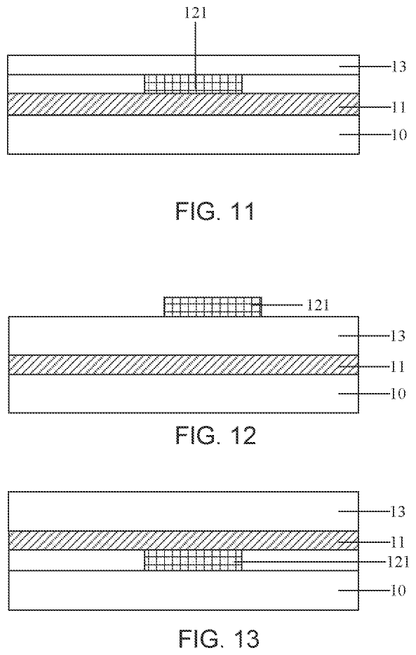

In some examples, the method includes: as shown in FIG. 9, forming the light-emitting device 11 on the base 10; as shown in FIG. 10, forming the color resist layer 121 on an encapsulation layer 13; as shown in FIG. 11, encapsulating the light-emitting device 11 by using the encapsulation layer 13 on which the color resist layer 121 has been formed, so that the color resist layer 121 is located between the light-emitting device 11 and the encapsulation layer 13. Here, the encapsulation layer 13 is a rigid encapsulation substrate.

In some other examples, the method includes: as shown in FIG. 12, forming the light-emitting device 11, the encapsulation layer 13 and the color resist layer 121 sequentially on the base 10. In this case, the encapsulation layer 13 may be a flexible encapsulation layer or a rigid encapsulation substrate.

In some other embodiments, the light-emitting device 11 is a bottom-emission light-emitting device, The method includes: as shown in FIG. 13, forming the color resist layer 121, the light-emitting device 11 and the encapsulation layer 13 sequentially on the base 10. In this case, the encapsulation layer 13 may be a flexible encapsulation layer or a rigid encapsulation substrate.

The method of the OELD display panel provided in the embodiments of the present disclosure has the same beneficial effects as the above OELD display panel 2, which is repeated herein.

The foregoing descriptions are merely specific implementations of the present disclosure, but the protection scope of the present disclosure is not limited thereto. Changes or replacements that any person skilled in the art could conceive of within the technical scope of the present disclosure shall be included in the protection scope of the present disclosure. Therefore, the protection scope of the present disclosure shall be subject to the protection scope of the claims.

1. An OLED display panel having a display region including a plurality of sub-pixel regions, the plurality of sub-pixel regions including red sub-pixel regions; the OLED display panel comprising:
a base;
light-emitting devices disposed on the base and located in the red sub-pixel regions, a light-emitting device having a microcavity structure, and a length of the microcavity of the light-emitting device being in a range from 100 nm to 500 nm; the light-emitting device being configured to emit red light; and
color resist layers disposed in the red sub-pixel regions and located at light-exit sides of the light-emitting devices, a color resist layer being configured such that a transmittance of light with a wavelength of 585 nm or above is greater than a transmittance of light with a wavelength of below 585 nm.

2. The OLED display panel according to claim 1, wherein the color resist layer is configured such that a transmittance of light with a wavelength of 595 nm or above is greater than a transmittance of light with a wavelength of below 595 nm.

3. The OLED display panel according to claim 2, wherein the color resist layer is configured such that a transmittance of light with a wavelength of 605 nm or above is greater than a transmittance of light with a wavelength of below 605 nm.

4. The OLED display panel according to claim 1, wherein the length of the microcavity of the light-emitting device is greater than 200 nm and less than 500 nm.

5. The OLED display panel according to claim 4, wherein the length of the microcavity of the light-emitting device is greater than 200 nm and less than or equal to 350 nm.

6. The OLED display panel according to claim 4, wherein the length of the microcavity of the light-emitting device is greater than 200 nm and less than or equal to 330 nm.

7. The OLED display panel according to claim 4, wherein the length of the microcavity of the light-emitting device is greater than 200 nm and less than or equal to 300 nm.

8. The OLED display panel according to claim 1, wherein the color resist layer is made of an organic polymer.

9. The OLED display panel according to claim 1, further comprising; an encapsulation layer disposed on a side of the light-emitting device away from the base.

10. The OLED display panel according to claim 1, further comprising; pixel driving circuits disposed between the light-emitting devices and the base, a pixel driving circuit being configured to drive the light-emitting device to emit light.

11. The OLED display panel according to claim 1, wherein the plurality of sub-pixel regions further includes green sub-pixel regions adjacent to the red sub-pixel regions; and
the color resist layer is also located in a region between the red sub-pixel region and a green sub-pixel region.

12. The OLED display panel according to claim 1, wherein the plurality of sub-pixel regions further includes blue sub-pixel regions adjacent to the red sub-pixel regions; and
the color resist layer is also located in a region between the red sub-pixel region and a blue sub-pixel region.

13. An OLED display apparatus, comprising the OLED display panel according to claim 1.

14. A method of manufacturing an OLED display panel, the OLED display panel having a display region including a plurality of sub-pixel regions, the plurality of sub-pixel regions including red sub-pixel regions, the method comprising:
forming light-emitting devices on a base and in the red sub-pixel regions, a light-emitting device having a microcavity structure, and a length of the microcavity of the light-emitting device being in a range from 100 nm to 500 nm; the light-emitting device being configured to emit red light; and
forming color resist layers in the red sub-pixel regions and at light-exit sides of the light-emitting devices, a color resist layer being configured such that a transmittance of light with a wavelength of 585 nm or above is greater than a transmittance of light with a wavelength of below 585 nm.

15. The method according to claim 14, wherein the light-emitting devices are top-emission light-emitting devices;
forming the light-emitting devices and the color resist layers includes:
forming the color resist layers on an encapsulation layer; and
encapsulating the light-emitting devices by using the encapsulation layer on which the color resist layers have been formed, so that the color resist layers are located between the light-emitting devices and the encapsulation layer.

16. The method according to claim 14, wherein the light-emitting devices are top-emission light-emitting devices;
forming the light-emitting devices and the color resist layers includes:
forming the light-emitting devices, an encapsulation layer and the color resist layers sequentially on the base.

17. The OLED display panel according to claim 9, wherein the light-emitting devices are top-emission light-emitting devices, and the color resist layers are arranged on a side of the encapsulation layer away from the light-emitting devices.

18. The OLED display panel according to claim 9, wherein the light-emitting devices are top-emission light-emitting devices, and the color resist layers are arranged between the encapsulation layer and the light-emitting devices.

19. The OLED display panel according to claim 9, wherein the light-emitting devices are bottom-emission light-emitting devices, and the color resist layers, the light-emitting devices and the encapsulation layer are sequentially arranged on the base.

20. The method according to claim 14, wherein the light-emitting devices are bottom-emission light-emitting devices;
forming the light-emitting devices and the color resist layers includes:
forming the color resist layers, the light-emitting devices and an encapsulation layer sequentially on the base.
